(19) United States
(12) Patent Application Publication
(10) Pub. No.: US 2012/0193667 A1
(43) Pub. Date: Aug. 2, 2012

(54) Method for Controlling Fluidity of Phosphor, Phosphor and Phosphor Paste

(75) Inventors: Seong Jae CHOI, Gyeonggi-do (KR); Dong Kee YI, Gyeonggi-do (KR); Seon Mi YOON, Gyeonggi-do (KR); Hyeon Jin SHIN, Gyeonggi-do (KR); Jae Young CHOI, Gyeonggi-do (KR)

(73) Assignee: Samsung Electro-Mechanics Co., Ltd., Suwon-si (KR)

(21) Appl. No.: 13/439,078

(22) Filed: Apr. 4, 2012

Related U.S. Application Data
(62) Division of application No. 11/748,297, filed on May 14, 2007.

(30) Foreign Application Priority Data
Oct. 28, 2006 (KR) 1020060105357

(51) Int. Cl. H01L 33/44; H01L 33/52

(52) U.S. Cl. 257/98; 438/27; 257/E33.061; 257/E33.059

(57) ABSTRACT

Disclosed herein is a method for controlling the fluidity of a phosphor, a phosphor and a phosphor paste, the method comprising the steps of: treating the surface of a phosphor with a silane compound comprising a double bond; and polymerizing the monomer on the surface of the phosphor to form a polymer membrane thereon. The phosphor having the polymer membrane formed thereon exhibits significantly stabilized fluidity within a polymer encapsulant.

### CROSS-REFERENCE TO RELATED PATENT APPLICATION

This is a divisional application of U.S. patent application Ser. No. 11/748,297 filed on May 14, 2007 and claims priority under 35 U.S.C. §119(a) to Korean Patent Application No. 2006-105357 filed on Oct. 28, 2006, the entire contents of which are hereby incorporated by reference.

### BACKGROUND OF THE INVENTION

1. Field of the Invention

Exemplary embodiments of the present invention relate to a method for controlling the fluidity of a phosphor, a coated phosphor, and a phosphor paste. More particularly, exemplary embodiments of the present invention relate to a method for controlling the fluidity of a phosphor which is characterized by treating the surface of the phosphor with a silane compound containing a double bond, and polymerizing a monomer on the surface of the phosphor to form a polymer membrane thereon.

2. Description of the Related Art

In general, a light emitting device such as a laser diode or a light emitting diode (LED) emits light at a particular wavelength. This restricts laser diodes or light emitting diodes to emitting light at only particular desired wavelengths. Therefore, in case where a light source that emits light at a variety of wavelengths is desired, a light of desired wavelength is obtained by coating a phosphor on an LED chip. For example, in order to obtain a white light emitting device blue light is combined with yellow light by coating a phosphor that produces yellow excitation light upon being activated by a blue light emitting diode chip.

Such sources of white light such as the white LED have been considered as inexpensive substitutes for paper-thin light sources, backlights of liquid crystal displays, display units of notebook computers, dome lights of vehicles and other light sources for illumination.

For the fabrication of LED, a phosphor is mixed with a polymer encapsulant such as an epoxy resin, a poly dimethyl siloxane (PDMS), an acryl resin, or the like, which is capable of being packaged on an LED chip. The mixture comprising the phosphor and the polymer encapsulant is coated on the LED chip, and then cured.

In the fabricating process of such LEDs, a phosphor and a polymer encapsulant such as PDMS are mixed, and thereafter, the mixture is disposed on a chip by using a syringe, as depicted in FIG. 1. In the process, it is important to load the mixture on the chip in an amount that enables a uniform distribution of the mixture on the chip. FIG. 2 is a graph representing a scatter diagram obtained in an example where a paste prepared by mixing a phosphor and a polymer encapsulant is dispensed by using a device of FIG. 1.

As described in FIG. 2, in the prior art, since the phosphors are widely dispersed around an E area, and in a B area or an F area as well as in an E area, the amount of coating of the phosphor on a chip may be varied according to time, whereby each of the fabricated LEDs has a different chromatic coordinate. It is desirable for all of the phosphors to be uniformly dispersed with the area labeled E. However because of differences in specific gravity between the phosphors and the polymer encapsulant, the amount of coating of the phosphors on the chip vary widely with time, and hence the phosphors are widely dispersed over the areas labeled E, B and F in the FIG. 2.

This is because the phosphors sink due to the difference in specific gravity between the phosphor and the polymer encapsulant. To minimize this problem, the phosphors should not precipitate within the polymer encapsulant with the passage of time and they should be uniformly dispersed as well.

Korean Patent Laid-open Publication No. 10-2004-42241 discloses a method for increasing the hydrophobicity of a phosphor by removing a hydrophilic group with a silane compound. However, this method does not result in the improving of the dispersibility of the phosphor within the encapsulant matrix. Japanese Patent Laid-open Publication No. 2003-37295 describes a method for improving dispersibility within a matrix by coating a phosphor with a silane compound. This method, however, drastically increases viscosity of the mixture of the encapsulant and the phosphor, leading to the difficulties in applying the mixture to a chip to obtain light of the desired wavelength. Thus, is therefore a need for the development of a method for controlling fluidity of a phosphor-encapsulant mixture so as to prevent the precipitation of a phosphor within a polymer encapsulant as well as to increase the dispersibility by uniformly mixing the phosphor.

### SUMMARY

In one embodiment, the present invention provides a method for controlling the fluidity of a phosphor, which decreases the rate of settling of a phosphor within a polymer encapsulant by reducing the density of the phosphor and thereby minimizing the occurrence of microturbulence.

In one embodiment, the present invention provides a method for controlling the fluidity of a phosphor-polymer encapsulant mixture which decreases that rate of settling of a phosphor within a polymer encapsulant by reducing density of a phosphor and also minimizing or preventing the occurrence of microturbulence therein. This is generally accomplished by increasing the hydrophobic property of the phosphor.

In another embodiment, the invention provides a phosphor having improved fluidity obtained by the method for controlling fluidity of a phosphor according to the present invention.

In another embodiment, the present invention provides a phosphor paste comprising a mixture of the phosphor coated with the polymer and a polymer encapsulant, and an LED prepared by using the same.

In yet another embodiment, there is provided a method for controlling fluidity of a phosphor, comprising: treating the surface of a phosphor with a silane compound containing a double bond; and mixing the surface-treated phosphor, a monomer and a polymerization initiator and polymerizing the monomer on the surface of the phosphor to form a polymer membrane thereon.

In accordance with another aspect of the present invention, there is provided a phosphor having improved fluidity that exhibits reduced settling speed and inhibits the occurrence of microturbulence within a polymer encapsulant.

In accordance with yet another aspect of the present invention, there is provided a phosphor paste comprising a mixture of the phosphor having improved fluidity and a polymer encapsulant, and an LED prepared by using the same.

### BRIEF DESCRIPTION OF THE DRAWINGS

The aforementioned features and other advantages of embodiments of the present invention will be more clearly understood from the following detailed description taken in conjunction with the accompanying drawings, in which:

FIG. 1 is a perspective view schematically illustrating a device for dispensing a phosphor on an LED chip;

FIG. 2 is a graph representing a scatter diagram obtained in the case where a paste prepared by mixing a phosphor and a polymer encapsulant is dispensed by using the device of FIG. 1;

FIG. 3 is an exemplary schematic view that depicts one method for controlling the fluidity of a phosphor according to an exemplary embodiment of the present invention;

FIG. 4 is a reaction scheme showing a chemical reaction for treating the surface of a phosphor with a silane compound and subsequently polymerizing in its presence a styrene monomer according to an exemplary embodiment of the present invention;

FIG. 5 is a view schematically illustrating a chemical structure of the phosphor coated with a polymer, which is obtained by the chemical reaction described in FIG. 4;

FIG. 6 is a photograph that shows the measurement results of hydrophobic properties of phosphors prepared in Example 1 and Comparative Example 1; and

FIG. 7 is a graph showing a change in viscosities of phosphors prepared according to Example 1 and Comparative Examples 1 and 2 in terms of time.

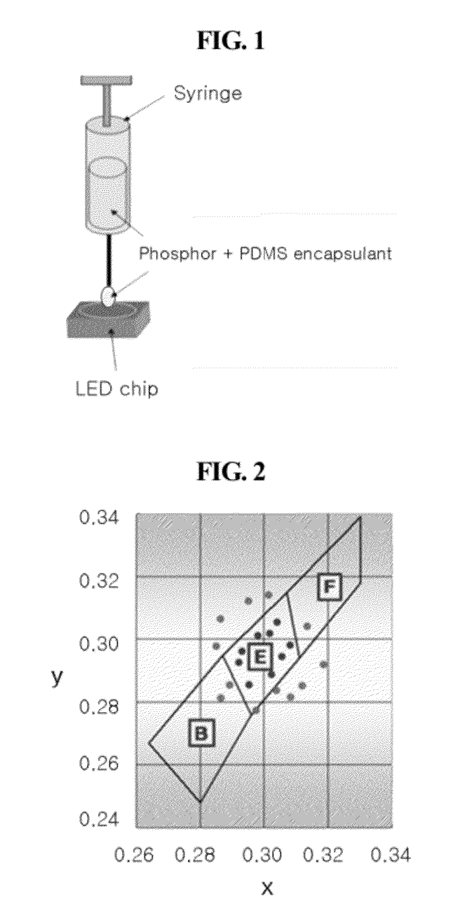

### DETAILED DESCRIPTION OF THE PREFERRED EMBODIMENTS

Hereinafter, exemplary embodiments of the present invention will be explained in more detail with reference to the accompanying drawings.

The method for controlling fluidity of a phosphor is characterized by a process comprising: treating the surface of a phosphor with a silane compound containing a double bond; and mixing the surface-treated phosphor, a monomer and a polymerization initiator and initiating polymerization on the surface of the phosphor to form a polymer film on the surface of the phosphor.

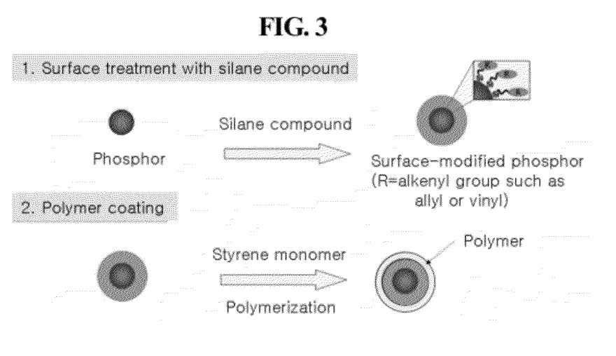

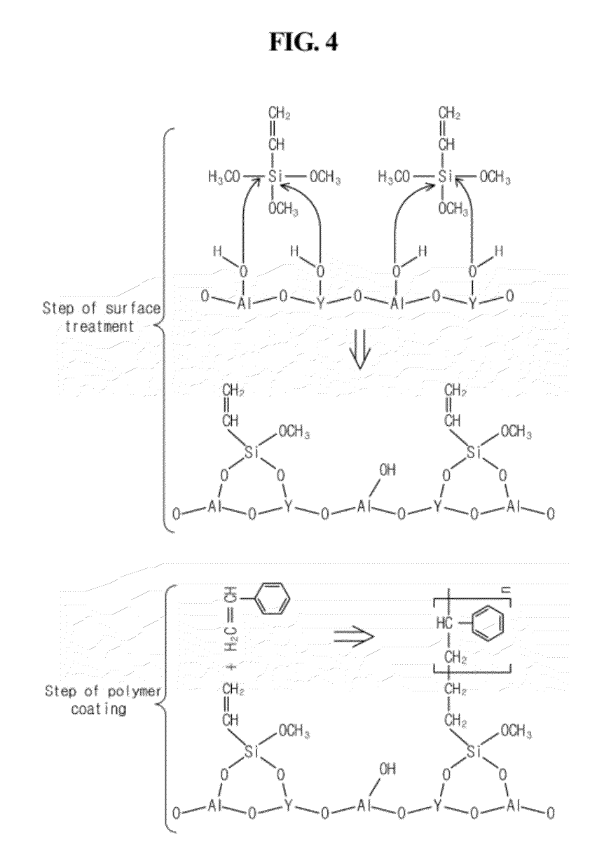

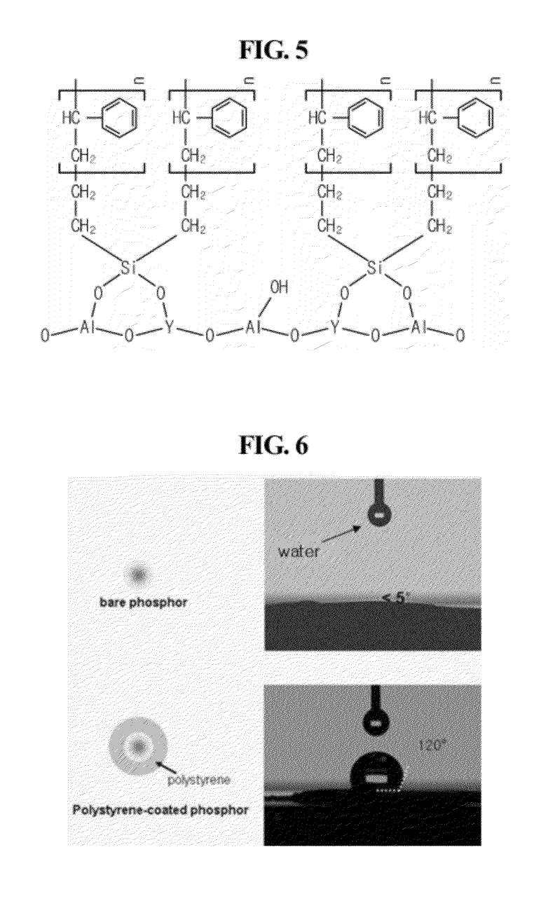

FIG. 3 is a schematic that depicts a method for controlling the fluidity of a phosphor according to an exemplary embodiment of the present invention. FIG. 4 depicts a chemical reaction used to treat the surface of a phosphor with a silane compound followed by the addition and polymerization of styrene monomer onto the silane treated phosphor. FIG. 5 is a schematic view illustrating a chemical structure of the phosphor coated with a polymer which is obtained by the chemical reaction described in FIG. 4.

Hereinafter, each step of the method according to the present invention will be described in detail.

### (1) Step of Surface Treatment

The method of the present invention first comprises the step of treating the surface of a phosphor with a silane compound. Referring to FIGS. 3 and 4, when the phosphor in the form of an oxide comes into contact with a water molecule in the air, the oxide group can undergo hydrogen bonding with the water molecule to form a hydroxyl group on the surface of the phosphor. If the surface of such a phosphor is treated with a silane compound, an alkoxy group of the silane compound is detached therefrom by coupling to the hydroxyl group of the phosphor, and the silane compound is reacted to the surface of the phosphor. The reaction of the silane compound to the surface of the phosphor causes the phosphor to become hydrophobic and the reacted silane compound contains a double-bond functional group (alkenyl group), leading to the induction of the polymer polymerization.

The silane compound employable in the present invention includes one or more alkoxy groups and one or more alkenyl groups such as an allyl group or a vinyl group. Preferable examples of the silane compound may be represented by the following Formula 1:

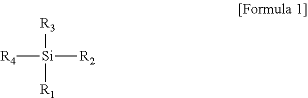

wherein R₁ is C₁₋₆ alkoxy; R₂, R₃ and R₄ are independently hydrogen, C₁₋₂₀ linear, branched or circular alkyl, C₁₋₆ alkoxy, C₂₋₂₀ alkenyl; and at least one of R₂, R₃ and R₄ is C₂₋₂₀ alkenyl.

Particular examples of the silane compound of Formula 1 may include allyltrimethoxysilane, diallyldimethoxysilane, allyltrietoxysilane, allyltripropoxysilane, allyltripthoxysilane, allyltripentyloxysilane, allyltrihexyloxysilane, allylmethoxysilane, vinyl trimethoxysilane, 1-butenyltrimethoxysilane and styryltrimethoxysilane, or the like, or a combination comprising at least one of the foregoing.

The phosphor used in the present invention may be an organic or an inorganic phosphor, and there is no limitation on the kind or the composition thereof so long as it is a phosphor in the form of an oxide. The phosphor suitable for the present invention may include a blue phosphor, a green phosphor and a red phosphor.

Suitable examples of red phosphors that can be used in the present invention are (Y,Gd)BO₃:Eu, Y(V,P)O₄:Eu, (Y,Gd)O₃:Eu, La₂O₂S:Eu³⁺ or the like, or a combination comprising at least one of the foregoing red phosphors. In an exemplary embodiment, it is desirable to use (Y,Gd)BO₃:Eu as the red phosphor.

Suitable examples of green phosphors that can be used in the present invention are BaMgAl₁₀O₁₇:Eu,Mn, Zn₂SiO₄:Mn, (Zn,A)₂SiO₄:Mn (where A is an alkaline earth metal), MgAlₓO_{y}:Mn (where x is an integer in the range of 1 to 10 and y is an integer in the range of 1 to 30), LaMgAlₓO_{y}:Tb (where x is an integer in the range of 1 to 14 and y is an integer in the range of 8 to 47), ReBO₃:Tb(where Re is at least one rare-earth elements selected from the group consisting of Sc, Y, La, Ce, and Gd), (Y,Gd)BO₃:Tb, or the like, or a combination comprising at least one of the foregoing green phosphors.

Suitable examples of the blue phosphors are Sr(PO₄)₃Cl:Eu²⁺, ZnS:Ag, Cl, CaMgSi₂O₆:Eu, CaWO₄:Pb, Y₂SiO₅:Eu, or the like, or a combination comprising at least one of the foregoing green phosphors.

Treating the surface of a phosphor with a silane compound comprises dispersing the phosphor in a solvent, adding a saline compound thereto followed by reaction, filtering the mixture, and washing and drying a filtrate. When the mixture of the phosphor and the solvent is subjected to reaction with the silane compound, a catalyst such as triethylamine may be added thereto. The reaction may be conducted at a temperature in the range of room temperature to about 100° C. for about 30 minutes to about 12 hours. When the filtration, washing and drying steps have been completed, the silane compound having a double bond is conjugated to the surface of the phosphor, as depicted in FIG. 4.

### (2) Step of Polymer Coating

Subsequently, the surface-treated phosphor in the above step (1), a monomer and a polymerization initiator are mixed and then subjected to polymerization of the monomer on the surface of the phosphor to form a polymer membrane on the surface of the phosphor.

When the polymerization is initiated by adding the monomer and polymerization initiator, the monomer becomes polymerized from an alkenyl group of the silane compound, leading to a polymer coating on the surface of the phosphor. FIG. 4 shows that a polymer membrane is formed by polymerizing a vinyl group of the silane compound with a styrene monomer in the step of polymer coating.

Examples of suitable monomers used in the polymerization upon the surface of the phosphor are styrene, propylene, vinylchloride, isobutylene, acrylonitrile, methylmethacrylate, 2-vinylpyrridine, isoprene, or the like, or a combination comprising at least one of the foregoing monomers.

Examples of suitable polymerization initiators are potassium persulfate, hydrogen peroxide, cumyl hydroperoxide, di-tertiary butyl peroxide, dilaurylperoxide, acetylperoxide, benzoylperoxide, or the like, or a combination comprising at least one of the foregoing monomers.

There is no particular limitation on the polymer polymerization method for forming a polymer membrane. The polymerization reaction may be conducted by mixing the surface-treated phosphor with the monomer and performing emulsion polymerization or suspension polymerization of the monomer.

Another aspect of the present invention is directed to a phosphor having improved fluidity obtained by the method for controlling fluidity of a phosphor according to the present invention.

FIG. 5 represents the chemical structure of one example of a phosphor according to the present invention. The phosphor described in FIG. 5 is YAG (yttrium aluminum garnet), and subjected to surface treatment with a silane compound and polymerization with styrene monomer, leading to the formation of a polystyrene polymer membrane.

As a result of the reaction with the polymer encapsulant, the phosphor particles exhibit a lower density than the phosphor particles without the polymeric encapsulant. As a result of the lowered coating, the phosphor particles exhibit a decreased settling speed (i.e., the settle more slowly). Further, the presence of an organic encapsulant on the phosphor's surface turns the surface hydrophobic. Thus, the occurrence of microturbulence can be inhibited within the polymer encapsulant.

If the surface of the existing phosphor in the form of an oxide (bare phosphor) comes into contact with a water molecule in the air, a hydroxyl group is reacted thereto, which renders the surface hydrophilic. This results in the occurrence of microturbulence caused by the difference in physical properties between the hydrophilic phosphor and the hydrophobic polymer encapsulant. The present invention can solve the above problem by modifying the surface of a phosphor to have a hydrophobic property through the use of a silane-based compound, as described above.

In general, the settling speed (v) of a phosphor is proportional to the difference in density (Δρ) of the phosphor from that of the media into which it permitted to settle. In the existing phosphor, if its size within a polymer encapsulant is increased, the fluidity becomes unstable due to the increased settling speed, which may cause a problem that all phosphors are not included in a target area (E) and exhibit a broad scatter diagram, as in the coordinate of FIG. 2. On the contrary, the phosphor of the present invention reduces a total density by coating with a polymer having low density, thereby decreasing its settling speed and thus exhibiting stable fluidity within a polymer encapsulant. The settling rate or velocity is determined by the mathematical formula 1 below:

$$v = \frac{2}{9} \frac{Δρ \times {d}^{2}}{Δμ} \qquad [ Mathematical formula 1 ]$$

wherein v is a settling speed; Δρ is a density difference; d is a diameter of the phosphor particle after coating; and Δμ is a viscosity difference.

Yet another aspect of the present invention relates to a phosphor paste comprising the mixture of the phosphor showing improved fluidity and a polymer encapsulant.

Suitable examples of polymer encapsulants are acryl, epoxy, polyimide, silicone, silicone-epoxy hybrid resin, poly dimethyl siloxane resin, phenol resin, polyurethane resin, amino resin, polyester resin, or the like, or a combination comprising at least one of the foregoing polymer encapsulants.

The phosphor paste may be prepared by mixing the phosphor showing improved fluidity according to the present invention with the polymer encapsulant, and fully mixing them through a blending process such as ball milling.

In one embodiment, the phosphor paste may be manufactured in other devices that can apply shear, extensional or elongational forces. Examples of such devices are extruders, single and/or twin screw extruders, Buss Kneaders, Henschel mixers, Waring blenders, or the like, or a combination of the aforementioned devices.

The phosphor paste of the present invention may further comprise other additives such as dispersing agents, plasticizers, labeling agents, anti-oxidants, mold release agents, viscosity modifiers, leveling agents, antifoamers and the like, without deteriorating its physical properties. All of these additives are well-known to those skilled in the art to the extent that they can be commercially obtained.

The phosphor paste of the present invention may be used in the fabrication of a light emitting device such as light emitting diodes (LEDs). For example, the light emitting device may be fabricated by surrounding an LED placed in a lead frame with the polymer encapsulant dispersed with the phosphor and sealing the polymer encapsulant, a wire and the lead frame with a sealing resin.

The light emitting device fabricated by using the phosphor of the present invention can be applied to a paper-thin light source, a backlight of a liquid crystal display, a display unit of a notebook computer, a dome light of a vehicle and a light source for illumination. In the light emitting device fabricated by using the polymer-coated phosphor of the present invention, since a uniform amount of the phosphor can be loaded on an LED chip, it is possible to decrease defects such as those involving movement of a chromatic coordinate, thereby manufacturing the LED with a high production yield and also minimizing defects.

Now, exemplary embodiments of the present invention will be described in more detail with reference to the following examples. However, these examples are given for the purpose of illustration merely and thus are not to be construed as limiting the scope of the invention.

### EXAMPLES

### Example 1

### (1) Silane Treatment

5 g of YAG powders(Cerium-doped Yttrium aluminium garnet, Y3Al5O12 (Nemoto Blue, Japan)) as a phosphor was added to 25 ml of toluene and vigorously stirred. Then, the phosphor/toluene mixture was mixed with 2 ml of allyltrimethoxysilane (where R₁, R₂ and R₃ are OCH₃, and R₄ is CH₂═CHCH₂—) and reacted at 60° C. for 12 hours. After the reaction was completed, the reaction mixture was filtered with a 1 micrometer filter paper and washed with toluene three times or more while filtering. The silane-treated phosphor thus obtained was dried by a dry oven at 100° C. for 4 hours or more.

### (2) Polymer Coating

After 5 g of the silane-treated phosphor and 5 ml of a styrene monomer were mixed and vigorously stirred, 50 ml of distilled water was slowly dropped in the phosphor/styrene monomer mixture. While the mixture was vigorously stirring until an emulsion was formed, it was gradually heated up to 70° C. After reaching 70° C., 0.08 g of potassium persulfate (K₂O₈S₂) was added to the reaction mixture, the mixture was reacted while refluxing for 12 hours or more. After the reaction was completed, the reaction mixture was filtered with a 1 micrometer filter paper and washed with toluene three times or more while filtering. The polymer-coated phosphor thus obtained was dried by a dry oven at 100° C. for 4 hours or more.

### Comparative Example 1

In order to compare the effect of the method for controlling fluidity of a phosphor according to the present invention, YAG phosphor powders that are commercially available on the market were prepared. These powders are the same as those employed in Example 1.

### Comparative Example 2

The phosphor was prepared by the same method as described in Example 1 except that after the surface of the phosphor was treated with a silane compound, it was not subjected to polymer coating.

### Test Example 1: Measurement of Hydrophobic Property

Hydrophobic properties of the phosphors prepared in Example 1 and Comparative Example 1 were assessed by measuring a contact angle with a water contact angle-measuring device, and the results are shown in FIG. 6.

As described in FIG. 6, it was confirmed that while the uncoated phosphor is miscible in water, the polymer-coated phosphor shows a very large contact angle when bringing into contact with water. Since the surface of the polymer-coated phosphor of the present invention was modified to be hydrophobic, it is capable of preventing the occurrence of microturbulence by the difference in physical properties between the surfaces of the phosphor and the polymer encapsulant.

### Test Example 2: Estimation of Viscosity Change According to Shear Rate

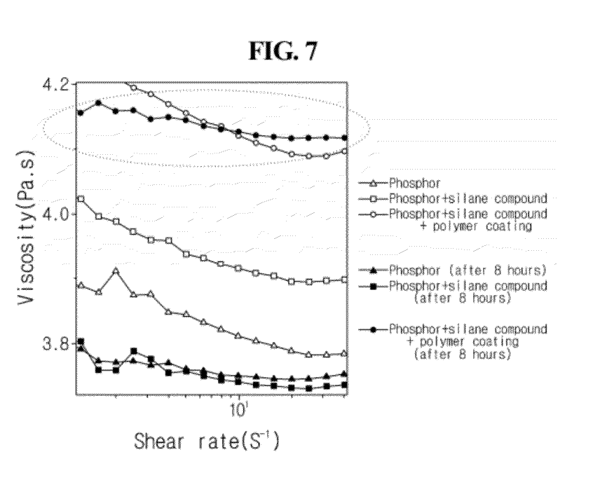

After 5 g of the polymer-coated phosphor was mixed with 20 g of PDMS, the mixture was mixed with a zirconia ball (5 mm in diameter) in a mixing vessel. The mixture was then subjected to ball milling for 4 hours or more so that the polymer-coated phosphor was thoroughly mixed with PDMS used as an encapsulant. The change in viscosity was observed while increasing the shear rate of the mixture by selectively taking only its upper part out of the mixture, and the results are shown in FIG. 7. At this time, the shear rate was measured during the preparation of a phosphor paste and 8 hours after the preparation, and the results are shown in FIG. 7.

As can be seen from FIG. 7, in case of the phosphor pastes prepared by using the phosphors of Comparative Examples 1 and 2, their viscosities were gradually decreased with the passage of time. The reason for the decrease with the passage of time is because that there is little phosphor in the upper part of the paste mixture due to the settling of the phosphor. On the contrary, it can be seen that, in case of the phosphor paste prepared by using the phosphor of Example 1, the viscosity of the mixture of the phosphor and the PDMS encapsulant is nearly constant with the passage of time. As a result, it can be confirmed that in case where the phosphor of the present invention is used in a polymer encapsulant system such as a poly dimethyl siloxane resin, the precipitation of the phosphor was prevented through polymer coating and the dispersibility was remarkably improved by uniformly mixing the phosphor.

As is apparent from the foregoing, when the surface of a phosphor is coated with a polymer, the density of the phosphor is reduced, thereby decreasing the settling speed thereof within a polymer encapsulant. Also, the increase in the hydrophobicity of the phosphor upon coating the phosphor with a polymer encapsulant prevents the occurrence of microturbulence. In addition, because of the reduced density of the phosphor after encapsulation, there is a uniform distribution of the phosphor when the mixture is disposed upon a LED chip. This prevents defects and improves production yields in the fabrication of the LED.

Although the preferred embodiments of the present invention have been disclosed for illustrative purposes, those skilled in the art will appreciate that various modifications, additions and substitutions are possible, without departing from the scope and spirit of the invention as disclosed and claimed in the accompanying claims.

What is claimed is:

1. A method for manufacturing light emitting device, comprising the steps of:
treating the surface of a phosphor with a silane compound that comprises an alkoxy group and an alkenyl group to form a surface-treated phosphor in which the silane compound having an alkenyl group is conjugated to the surface of the phosphor, wherein the step of treating the surface of the phosphor is conducted by dispersing the phosphor in a solvent,
adding the silane compound thereto,
filtering the mixture, and washing and drying a filtrate;
mixing the surface-treated phosphor, a monomer and a polymerization initiator and initiating polymerization of the monomer on the surface of the phosphor to form a polymer film on the surface of the phosphor;
dispersing the phosphor having the polymer film inside a polymer encapsulant having a fluidity; and
surrounding an LED with the polymer encapsulant dispersed with the phosphor having the polymer film, wherein the step of forming the polymer film is conducted by mixing the surface-treated phosphor with the monomer and performing suspension polymerization of the mixture, and wherein the monomer is polymerized from the alkenyl group of the silane compound, and the alkenyl group comprises an allyl group.

2. The method according to claim 1, wherein the silane compound has a structure represented by the following Formula 1: 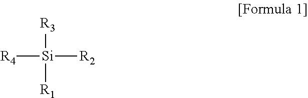
wherein R₁ is C₁₋₆ alkoxy; R₂, R₃ and R₄ are independently hydrogen, C₁₋₂₀ linear, branched or circular alkyl, C₁₋₆ alkoxy, C₂₋₂₀ alkenyl, at least one of R₂, R₃ and R₄ being C₂₋₂₀ alkenyl.

3. The method according to claim 1, wherein the silane compound is selected from the group consisting of allyltrimethoxysilane, diallyldimethoxysilane, allyltrietoxysilane, allyltripropoxysilane, allyltripthoxysilane, allyltripentyloxy, allyltrihexyloxysilane and allylmethoxysilane.

4. The method according to claim 1, wherein the monomer is one or more selected from the group consisting of styrene, propylene, vinylchloride, isobutylene, acrylonitrile, methylmethacrylate, 2-vinylpyrridine, and isoprene.

5. The method according to claim 1, wherein the phosphor is an inorganic phosphor or an organic phosphor.

6. The method according to claim 6, wherein the inorganic phosphor is one or more selected from the group consisting of Y₃Al₅O₁₂:Ce, (Y,Gd)BO₃:Eu, Y(V,P)O₄:Eu, (Y,Gd)O₃:Eu, La₂O₂S:Eu³⁺, BaMgAl₁₀O₁₇:Eu,Mn, Zn₂SiO₄:Mn, (Zn,A)₂SiO₄:Mn (where A is an alkaline earth metal), MgAlₓO_{y}:Mn (where x is an integer in the range of 1 to 10 and y is an integer in the range of 1 to 30), LaMgAlₓO_{y}:Tb (where x is an integer in the range of 1 to 14 and y is an integer in the range of 8 to 47), ReBO₃:Tb (where Re is one or more rare-earth elements selected from the group consisting of Sc, Y, La, Ce, and Gd), (Y,Gd)BO₃:Tb, Sr(PO₄)₃Cl:Eu²⁺, ZnS:Ag, Cl, CaMgSi₂O₆:Eu, CaWO₄:Pb, and Y₂SiO₅:Eu.

7. The method according to claim 1, wherein the initiator is one or more selected from the group consisting of potassium persulfate, hydrogen peroxide, cumyl hydroperoxide, di-tertiary butyl peroxide, dilaurylperoxide, acetylperoxide, and benzoylperoxide.

8. The method according to claim 1, wherein the polymer encapsulant is selected from the group consisting of acryl, epoxy, polyimide, silicone, silicone-epoxy hybrid resin, poly dimethyl siloxane resin, phenol resin, polyurethane resin, amino resin, polyester resin, and a combination comprising at least one of the foregoing polymer encapsulants.

9. A light emitting device prepared by using the method according to claim 1.

10. A light Source comprises the light emitting device according to claim 9.

11. A backlight unit comprises the light emitting device according to claim 9.

12. A dome light of vehicle comprises the light emitting device according to claim 9.
